(19) United States
(12) Patent Application Publication
(10) Pub. No.: US 2009/0114534 A1
(43) Pub. Date: May 7, 2009

(54) Sputtering Assembly

(76) Inventor: Geoffrey Green, Belmont, CA (US)

Correspondence Address: Director of IP, 5521 Hellyer Avenue, San Jose, CA, 95138, US

(21) Appl. No.: 12/203,062

(22) Filed: Sep. 2, 2008

Related U.S. Application Data
(60) Provisional application No. 60/969,528, filed on Aug. 31, 2007.

(51) Int. Cl. C23C 14/58; C23C 14/35

(52) U.S. Cl. 204/298.09; 204/298.16

(57) ABSTRACT

Methods and devices are provided for improved sputtering systems. In one embodiment of the present invention, a sputtering system for use with a substrate is provided. The system comprises of a sputtering chamber; at least one magnetron disposed in the chamber; and at least one, non-convection based cooling system in the sputtering chamber. This system may optionally use at least one chilled roller positioned along the path of the substrate. This chilled roller may be in the sputtering chamber or optionally, outside the sputtering chamber. This system may optionally include at least one emissivity based cooling apparatus located within the chamber for drawing heat away from the substrate. In another embodiment the present invention, the sputtering system may use a non-convection, non-conduction system for cooling the substrate. The system may use a non-contact cooling system that is spaced apart from the substrate. This system may optionally include at least one emissivity based cooling apparatus located within the chamber for drawing heat away from the substrate. Optionally, outside the sputtering chamber, at least one chilled roller positioned along the path of the substrate to further cool the substrate.

### CROSS-REFERENCE TO RELATED APPLICATION

The application claims priority to U.S. Provisional Application Ser. No. 60/969,528 filed Aug. 31, 2007, fully incorporated herein by reference for all purposes.

### FIELD OF THE INVENTION

This invention relates generally to deposition systems, and more specifically, sputtering systems for use with temperature sensitive substrates.

### BACKGROUND OF THE INVENTION

Physical vapor deposition (PVD) or sputtering is one method suitable for depositing material on a metal or metallized substrate. Some types of sputtering systems use a magnetron behind the sputtering target to enhance sputtering efficiency. Unfortunately, heating of the magnetron and/or the target above a designated processing temperature may adversely affect performance of the process by changing the sputtering rate or reducing sputtering uniformity of the target. Additionally, excess heat may cause mechanical features of the magnetron to wear out prematurely and otherwise shorten the lifetime of the sputtering system component. Furthermore, excess heat may cause undesirable thermal expansion of components within the chamber, which may interfere with tool performance.

To alleviate this problem, magnetrons are typically housed in a cooling cavity. A coolant, such as deionized water or ethylene glycol, is flowed through the cooling cavity to cool the backside of the target and to cool the magnetron. Although such cooling may help reduce the temperature of the magnetron and the target, traditional magnetron sputtering systems do not address thermal build-up that may occur in the substrate being coated. This is of particular concern for wide foil substrates of metal materials. In an in-line, roll-to-roll sputtering machine, the metal foil may exhibit certain undesirable qualities such as buckling, warping, or other undesirable release of stress. Furthermore, certain specific types of processes in solar or other device industries requires sputtering of material over partially completed cells or semiconductor devices. These partially completed devices may have much lower temperature thresholds than 600° C., above which the partially completed devices begin to deteriorate. The ability for drums to cool the material may also be limited due the ability to fully contact the metal foil against a cooling surface.

Although some known sputtering systems may include cooling systems for the magnetron or the target, the potential for using such sputtering on temperature sensitive target substrates remains limited. Therefore, a need exists in the art for an improved cooling system to cool target substrates used in magnetron sputtering apparatus.

### SUMMARY OF THE INVENTION

Embodiments of the present invention address at least some of the drawbacks set forth above. The present invention provides for the improved sputtering systems that may be used for substrate that may degrade at normal sputtering temperatures. Although not limited to the following, these improved module designs are well suited for roll-to-roll, in-line processing equipment. It should be understood that at least some embodiments of the present invention may be applicable to any type of solar cell, whether they are rigid or flexible in nature or the type of material used in the absorber layer. Embodiments of the present invention may be adaptable for roll-to-roll and/or batch manufacturing processes. At least some of these and other objectives described herein will be met by various embodiments of the present invention.

In one embodiment of the present invention, a sputtering system for use with a substrate is provided. The system comprises of a sputtering chamber; at least one magnetron disposed in the chamber; and at least one, non-convection based cooling system in the sputtering chamber. This system may optionally use at least one chilled roller positioned along the path of the substrate. By way of example and not limitation, these thermally controlled roller are not in the sputtering chamber in the present embodiment. In one embodiment, only the emissivity plate or sink is used in the sputtering chamber(s) for cooling. This chilled roller may be in the sputtering chamber or optionally, outside the sputtering chamber. This system may optionally include at least one emissivity based cooling apparatus located within the chamber for drawing heat away from the substrate. In one embodiment, the sputtering is not occurring on a substrate being cooled by direct contact/conduction.

In another embodiment the present invention, the sputtering system may use a non-convection, non-conduction system for cooling the substrate. The system may use a non-contact cooling system that is spaced apart from the substrate. This system may optionally include at least one emissivity based cooling apparatus located within the chamber for drawing heat away from the substrate. Optionally, outside the sputtering chamber, at least one chilled roller positioned along the path of the substrate to further cool the substrate.

In one embodiment of the present invention, a vacuum deposition system is provided with a processing chamber; at least one deposition unit in the chamber; at least one emissivity unit located within the chamber for drawing heat away from the substrate. In a specific implementation, the system includes a sputtering chamber; at least one magnetron disposed in the chamber; at least one cooling device positioned along the path of the substrate to come into physical contact with the substrate; and at least one emissivity-based heat sink located within the chamber for drawing heat away from the substrate.

Optionally, the following may adapted for any of the embodiments herein. In one embodiment, the cooling device is located outside the sputtering chamber. Optionally, the cooling device is located inside the sputtering chamber. Optionally, the cooling device comprises of a chilled roller. Optionally, the cooling device comprises of a chilled roller with a pliable coating on the roller. Optionally, the cooling device comprises of a chilled roller. Optionally, the cooling device cools by way of conduction. Optionally, a tensioner is positioned to pull the substrate against the cooling device for improved surface contact. Optionally, a tensioner is positioned to push the substrate against the cooling device for improved surface contact. Optionally, a plurality of cooling devices are positioned along the path of the substrate. Optionally, the cooling devices are positioned along the path of the substrate in an arrangement that increases normal force of the substrate against at least one surface of at least one of the cooling devices. Optionally, the cooling devices are positioned along the path of the substrate in an arrangement wherein the devices only contact a backside surface of the substrate. Optionally, the cooling devices are positioned along the path of the substrate in an arrangement wherein at least one of the devices contacts a backside surface of the substrate and at least one of the devices contacts a frontside surface of the substrate at the same or different location along the path. Optionally, at least a second sputtering chamber arranged to receive the substrate. Optionally, the second sputtering chamber includes at least one cooling device positioned along the path of the substrate to come into physical contact with the substrate; and at least one emissivity-based heat sink located within the chamber for drawing heat away from the substrate. Optionally, at least one cooling section between the sputtering chamber and the second sputtering chamber.

In another embodiment of the present invention, a sputtering system is provided comprising a sputtering chamber; at least one magnetron disposed in the chamber; at least one conduction-based cooling system positioned along the path of the substrate; and a cooling system to reduce the temperature of the substrate while the substrate is in the chamber, wherein the cooling system is not a chamber wall and is in an arrangement to cool the substrate by way of emissivity cooling. Optionally, the cooling system comprises of at least one emissivity mass positioned at least partially inside the chamber. Optionally, the cooling system comprises of at least one emissivity plate positioned at least partially inside the chamber.

A further understanding of the nature and advantages of the invention will become apparent by reference to the remaining portions of the specification and drawings.

### BRIEF DESCRIPTION OF THE DRAWINGS

FIG. 1 is a side view of a chamber according to one embodiment of the present invention.

FIG. 2 shows one configuration of a processing assembly according to one embodiment of the present invention.

FIG. 3 shows one configuration of a processing assembly according to another embodiment of the present invention.

FIG. 4 shows one configuration of a processing assembly according to another embodiment of the present invention.

FIG. 5 shows one configuration of a processing assembly according to another embodiment of the present invention.

FIG. 6 shows one configuration of a processing assembly according to another embodiment of the present invention.

FIG. 7 shows one configuration of a processing assembly according to another embodiment of the present invention.

FIG. 8 shows a close-up view on one building block of a processing assembly according to another embodiment of the present invention.

FIG. 9 shows one configuration of a processing assembly according to another embodiment of the present invention.

FIGS. 10-12 show embodiments of processing shields according to embodiments of the present invention.

### DESCRIPTION OF THE SPECIFIC EMBODIMENTS

It is to be understood that both the foregoing general description and the following detailed description are exemplary and explanatory only and are not restrictive of the invention, as claimed. It may be noted that, as used in the specification and the appended claims, the singular forms “a”, “an” and “the” include plural referents unless the context clearly dictates otherwise. Thus, for example, reference to “a material” may include mixtures of materials, reference to “a compound” may include multiple compounds, and the like. References cited herein are hereby incorporated by reference in their entirety, except to the extent that they conflict with teachings explicitly set forth in this specification.

In this specification and in the claims which follow, reference will be made to a number of terms which shall be defined to have the following meanings:

“Optional” or “optionally” means that the subsequently described circumstance may or may not occur, so that the description includes instances where the circumstance occurs and instances where it does not. For example, if a roller optionally contains a feature for a thermally conductive film, this means that the conductive film feature may or may not be present, and, thus, the description includes both structures wherein a roller possesses the conductive film feature and structures wherein the film feature is not present.

### Photovoltaic Module

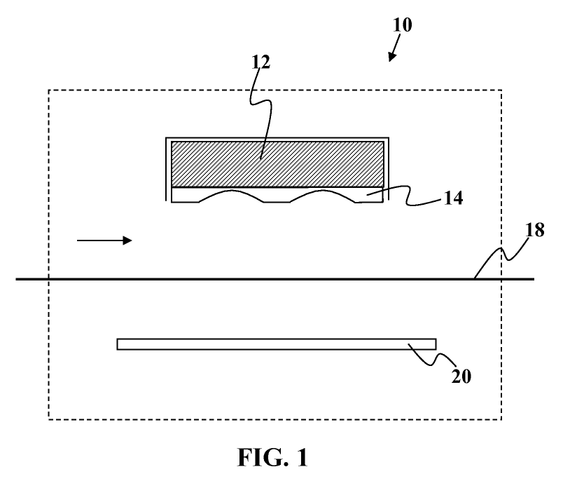

Referring now to FIG. 1, one embodiment of a sputtering chamber 10 according to the present invention will now be described. Although the size and shape of the chamber may vary, the sputtering chamber 10 should include at least one magnetron 12 and at least one target 14. Some embodiments may include multiple targets and/or multiple magnetrons. FIG. 1 shows that the target 14 has already been in use and has areas 16 where material has been used in the sputtering process. This embodiment shows that the substrate 18 may be positioned in the chamber with at least one surface facing the target 14. It should be understood that in one embodiment, the substrate may be a metal foil such as but not limited to stainless steel, titanium, aluminum, steel, iron, copper, molybdenum, a Mo coated stainless steel or aluminum foil, or alloys of the aforementioned. In some embodiments, the substrate may be a polymer or metallized polymer. In other embodiments, the substrate is coated with material(s) such as but not limited to an absorber precursor, a photovoltaic absorber layer (with or without junction partner), barrier layer, conductive barrier layer, insulating backside layer, anti-reflective layer, other layers of a photovoltaic stack, or other materials. In some embodiments, these coated layers may significantly reduce the maximum temperature that the substrate can withstand without damaging the materials. In one embodiment such as for material with junction partner thereon, the maximum processing temperature is about 200° C. or less. Optionally, the maximum processing temperature is about 190° C. or less. Optionally, the maximum processing temperature is about 180° C. or less. Optionally, the maximum processing temperature is about 170° C. or less. Optionally, the maximum processing temperature is about 160° C. or less. Optionally, the maximum processing temperature is about 150° C. or less. Optionally, the maximum processing temperature is about 140° C. or less. Optionally, the maximum processing temperature is about 130° C. or less. Optionally, the maximum processing temperature is about 120° C. or less. Optionally, the maximum processing temperature is about 110° C. or less. Optionally, the maximum processing temperature is about 100° C. or less.

By way of example and not limitation, the metal foil may be in a roll-to-roll configuration, individual pieces or coupons, or coupons coupled together to form an elongate roll. Various valving mechanisms such as but not limited to a pinch valve or the like may be used to maintain a vacuum, low vacuum, or similar atmosphere. These elements may be on the inlet, outlet, or other portion of the chamber.

As seen in FIG. 1, the present embodiment of the sputtering chamber 10 includes at least one emissivity based cooling element 20. As previously discussed, some substrates are particularly sensitive to excessive heat build-up that may deteriorate the quality of the sputtered layer, warp the underlying substrate, and/or damage the resulting device. As the magnetron is swept over the target, considerable energy is dissipated in the form of heat by the ions striking the surface of the target. The target is heated by this process. The substrate being processed is also heated in a similar fashion as material is deposited on it. It should understood that during sputtering, the atmosphere inside the chamber 10 may be at vacuum, at low vacuum, at very low vacuum, or at lower than atmospheric pressures. Thus, the ability to cool the substrate by way of convention techniques such as gas flow, gas convection, or the like is limited. Accordingly, it is desirable to use other thermal transfer techniques to reduce the heat of the substrate while it is inside the chamber. The embodiments herein may be cooling by molecular flow without viscous flow such as convection, conduction or the like.

By way of nonlimiting example, it should be understood that in one embodiment the combined size of the emissivity unit is at least 100% of the area of the substrate inside the sputter chamber. Optionally, the size of the emissivity unit is at least 90% of the area of the substrate inside the sputter chamber. Optionally, the size of the emissivity unit is at least 80% of the area of the substrate inside the sputter chamber. Optionally, the size of the emissivity unit is at least 70% of the area of the substrate inside the sputter chamber. Optionally, the size of the emissivity unit is at least 110% of the area of the substrate inside the sputter chamber. This is possible if a larger unit is used or if multiple units are used such as but not limited to those in other orientations relative to the substrate. Some may be above, below, and/or to the side of the substrate pass through the chamber.

By way of example and not limitation, one such technique involves using emissivity thermal energy transfer from the substrate to another body in or near the chamber. Emissivity or heat transfer through radiation takes place in the form of electromagnetic waves mainly in the infrared region. The radiation emitted by a body is the consequence of thermal agitation of its composing molecules. The emissivity of a material (usually written) is the ratio of energy radiated by the material to energy radiated by a black body at the same temperature. It is a measure of a material's ability to absorb and radiate energy. A true black body would have an ε=1 while any real object would have ε<1. Emissivity is a numerical value and does not have units. It may be defined as the ratio of the radiation emitted by a surface to the radiation emitted by a black body at the same temperature.

This emissivity depends on factors such as temperature, emission angle, and wavelength. However, a typical engineering assumption is to assume that a surface's spectral emissivity and absorptivity do not depend on wavelength, so that the emissivity is a constant. This is known as the grey body assumption. When dealing with non-black surfaces, the deviations from ideal black body behavior are determined by both the geometrical structure and the chemical composition, and follow Kirchhoff's law of thermal radiation: emissivity equals absorptivity (for an object in thermal equilibrium), so that an object that does not absorb all incident light will also emit less radiation than an ideal black body.

A black body is a hypothetic body that completely absorbs all wavelengths of thermal radiation incident on it. Such bodies do not reflect light, and therefore appear black if their temperatures are low enough so as not to be self-luminous. All blackbodies heated to a given temperature emit thermal radiation. The radiation energy per unit time from a blackbody is proportional to the fourth power of the absolute temperature and can be expressed with Stefan-Boltzmann Law

q=σT⁴A (1)

where

q=heat transfer per unit time (W)

σ=5.6703 10⁻⁸ (W/m²K⁴)—The Stefan-Boltzmann Constant

T=absolute temperature Kelvin (K)

A=area of the emitting body (m²)

The Stefan-Boltzmann Constant in Imperial Units

σ=5.6703 10⁻⁸ (W/m2K⁴)

=0.1714 10⁻⁸ (Btu/(h ft² oR⁴))

=0.119 10⁻¹⁰ (Btu/(h in² oR⁴))

If an hot object is radiating energy to its cooler surroundings the net radiation heat loss rate can be expressed like

q=εσ(Th⁴−Tc⁴)Ac (3)

where

Th=hot body absolute temperature (K)

Tc=cold surroundings absolute temperature (K)

Ac=area of the object (m²)

Radiation heat transfer allows for the exchange of thermal radiation energy between the substrate and one or more bodies in the chamber. Thermal radiation from the substrate is typically electromagnetic radiation in the wavelength range of about 0.1 to 100 microns (which encompasses the visible light regime), and arises as a result of a temperature difference between at least two bodies. No medium need exist between the two bodies for heat transfer to take place (as is needed by conduction and convection). Rather, the intermediaries are photons which travel at the speed of light.

The heat transferred into or out of an object by thermal radiation is a function of several components. These include its surface reflectivity, emissivity, surface area, temperature, and geometric orientation with respect to other thermally participating objects. In turn, an object's surface reflectivity and emissivity is a function of its surface conditions (roughness, finish, etc.) and composition.

Radiation heat transfer accounts for both incoming and outgoing thermal radiation. Incoming radiation can be absorbed, reflected, or transmitted. This decomposition can be expressed by the relative fractions,

1=ε_{reflected}+ε_{absorbed}+ε_{transmitted}

Since most solid bodies are opaque to thermal radiation, we can ignore the transmission component and write,

1=ε_{reflected}+ε_{absorbed}

To account for a body's outgoing radiation (or its emissive power, defined as the heat flux per unit time), one makes a comparison to a perfect body who emits as much thermal radiation as possible. Such an object is known as a blackbody, and the ratio of the actual emissive power E to the emissive power of a blackbody is defined as the surface emissivity e,

$$ɛ = \frac{E}{{E}_{blackbody}}$$

By stating that a body's surface emissivity is equal to its absorption fraction, Kirchhoff's Identity binds incoming and outgoing radiation into a useful dependent relationship,

ε=ε_{absorbed}

FIG. 1 shows only one emissivity plate 20. It should be understood that in other embodiments of the invention, more than one emissivity plate 20 may be used in each chamber. As seen in FIG. 1, the emissivity plate 20 may be planar in nature but is not limited to such a configuration. Others may use a curved, waved, or textured object. It may be oriented parallel to the substrate 18 and may be located on the side opposite the side of the planar magnetron target(s) 14. Optionally, the emissivity plate 20 or other emissivity cooling elements may be placed along the side wall of the chamber. The heat from sputtering may pass through the substrate and be emitted outward from the backside of the substrate and towards the emissivity plate 20.

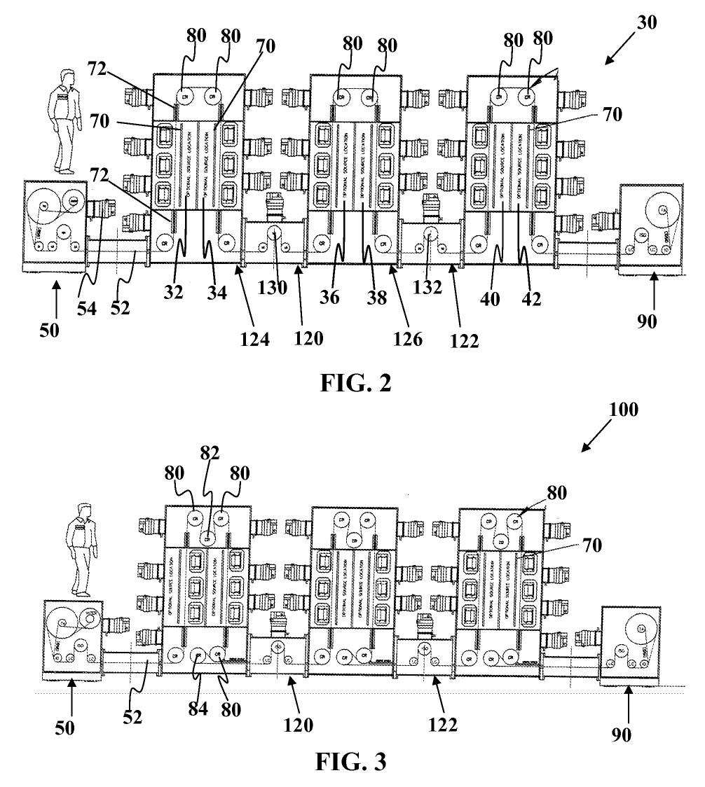

Referring now to FIG. 2, one embodiment of the sputtering system incorporating some of the aforementioned cooling devices will now be described. This embodiment shows a magnetron sputtering system 30 with a plurality of sputtering chambers 32, 34, 36, 38, 40, and 42. Although this embodiment is shown with a plurality of chambers, it should also be understood that the present application is also applicable to those embodiments using a single chamber. It should also be understood that the system may be adapted for use with a roll-to-roll substrate handling system, a conveyor type system, or as a batch system with the substrate as a plurality of discrete, individual objects.

As seen in the embodiment of FIG. 2, a substrate unwind unit 50 is positioned upstream from the sputtering chambers. The substrate 52 in the present embodiment comprises of an elongate flexible material that will wind its way through the various sputtering chambers. It should be understood that the sputtering chambers may be depositing the same or different materials. For roll-to-roll manufacturing, the unwind unit 50 will provide the substrate that pass through the chambers. In some embodiments, the substrate 52 may have a width of more than about 1 meter in width. Optionally, the substrate 52 may have a width of more than about 2 meters in width. Optionally, the substrate 52 may have a width of more than about 3 meters in width. The unwind unit 50 may be under vacuum, low vacuum, and/or sub-atmospheric pressure by way of a vacuum unit 54. Optionally, the unwind unit 50 is not under vacuum, only under low vacuum, or at some sub-atmospheric pressure. The unwind unit 50 may be designed to include a plurality of rollers to guide the substrate and place it under the proper tension. The chambers may incorporate leak-free or low leakage entrance gates valves to maintain the appropriate atmosphere inside the chamber. Optionally, some embodiments may include the entire supply roll (i.e. the substrate unwind unit 50 inside a vacuum chamber or area coupled to the first chamber).

As seen in FIG. 2, the substrate 52 passes through a first sputtering chamber 30. In the present embodiment, the chamber 30 includes a plurality of magnetrons with sputtering targets 60. In one embodiment, these may be planar magnetrons. Optionally, other embodiments may use magnetrons such as but not limited to rotatable magnetrons, rotary magnetrons or magnetrons of other configurations. Some embodiments may only have one sputtering target 60, while other may have multiple targets. The chamber 30 also includes at least one emissivity unit 70. By way of nonlimiting example, this embodiment of the invention shows the unit 70 as a planar plate. It should be understood of course, that other shaped devices such as but not limited to curved plates, non-rectangular plates, oval plates, discs, curved shells, curved dishes, rectangles, concave surfaces, convex surface, or other shaped masses may also be used. The unit 70 may be surface treated to be dimpled, bumped, or otherwise textured. In one embodiment, the emissivity unit 70 is black in color to maximize it absorption of emitted thermal radiation. Although the unit may be other colored, the unit 70 is preferably black, but is not limited to any particular color and may also be grey, dark colored, or otherwise colored. Optionally some embodiments may provide combinations of colors and/or shapes. If the unit 70 is black, this will more closely approximate the hypothetical black body which maximizes absorption. The black color may be formed via anodization, oxidation, paint, or other process. The entire unit 70 may be black, only a portion is black, or optionally only the surface facing or in line of sight of the substrate is black or other dark colored. The unit 70 may itself be coupled to a cooling unit to keep the unit 70 from overheating and at a temperature sufficient to absorb thermal radiation from the substrate. In one embodiment, the unit 70 may be maintained at a temperature less than the temperature of the substrate 52.

In one embodiment, the distance of the unit 70 from the substrate is about 10 mm or less. Optionally, the distance is about 15 mm or less. Optionally, the distance is about 20 mm or less. Optionally, the distance is about 25 mm or less. Optionally, the distance is about 30 mm or less. In other embodiments, the distance may be greater than those listed above. Some embodiments may have one portion of unit 70 closer to the substrate than another portion of the unit 70.

Optionally, the substrate may be free-spanned over the unit 70. Optionally, the substrate may be in contact with a bottom wall or other support surface in the chamber. Optionally, the substrate may be passed horizontally, vertically, or at some angle through the chamber. The unit 70 may be oriented as such to parallel and/or match the path of the substrate. Some embodiments may maintain the same gap or distance between them.

In one embodiment, it is desirable to maintain the substrate 52 below the substrate melting temperature. Optionally, it is desirable to keep the substrate 52 at a temperature at least about 10% away from the substrate melting temperature to prevent undesirable warping that may occur. Optionally, it is desirable to keep the substrate 52 at a temperature at least about 15% away from the substrate melting temperature to prevent undesirable warping that may occur. Optionally, it is desirable to keep the substrate 52 at a temperature at least about 20% away from the substrate melting temperature to prevent undesirable warping that may occur. Optionally, it is desirable to keep the substrate 52 at a temperature at least about 30% away from the substrate melting temperature to prevent undesirable warping that may occur. Optionally, it is desirable to keep the substrate 52 at a temperature at least about 40% away from the substrate melting temperature to prevent undesirable warping that may occur. Optionally, it is desirable to keep the substrate 52 at a temperature at least about 50% away from the substrate melting temperature to prevent undesirable warping that may occur. In some embodiments, this may be accomplished by use of unit 70 alone, in combination with one or other unit 70, or with other cooling device in or outside the chamber. Also, conduction baffles 72 may also be included at the entrance and/or exit of each of the sputtering chambers. These baffles 72 help to minimize the mixture of gas species that may be in the various chambers. The baffles 72 may also provide another source for a heat sink.

Referring still to FIG. 2, after the substrate 52 passes through the chamber 30, the substrate 52 may optionally be temperature regulated by other techniques such as but not limited to contact with thermal masses 80. In the present embodiment, the thermal masses 80 may be at lower temperatures than the substrate 52 to bring the substrate 52 to a more manageable temperature prior to going into another sputtering section of the system. In the present embodiment, some of these thermal masses 80 may comprise of thermally controlled rollers such as but not limited to chilled rollers. These thermally controlled rollers are not limited to chilling but may also be used to regulate temperature and may be used as heaters, coolers, or the like. Some embodiment may have thermally controlled rollers at different temperatures along the path of the substrate through the chamber(s). In one nonlimiting example, a first roller is configured to be at the same temperature as the next thermally controlled roller. Optionally, the first roller may be at a lower temperature than the next thermally controller roller. Optionally, the first roller may be at a higher temperature than the next thermally controller roller but still chill or lower the temperature of the substrate. Optionally, the first roller may be at a higher temperature than the next thermally controller roller but may warm the temperature of the substrate.

FIG. 2 shows that the present embodiment comprises of using at least two chilled rollers as thermal masses 80 in the area outside the sputter chamber 32 to reduce the temperature of the substrate 52 before it enters another sputtering chamber 34. The substrate 52 continues through a plurality of sputtering chambers (with or without emissivity units 70) preceded by and/or followed by thermal masses 80 to maintain the substrate 52 in a temperature range that minimizes warping or other undesirable effects from the heat absorbed during sputtering. Pinch valves, baffles, or other types of valving may be used to maintain the vacuum, low vacuum atmosphere, or sub-atmospheric pressure environment inside the sputtering chamber. After completing a pass through the chamber, a substrate rewind unit 90 is used to gather together the processed substrate back into a roll for ease of transport.

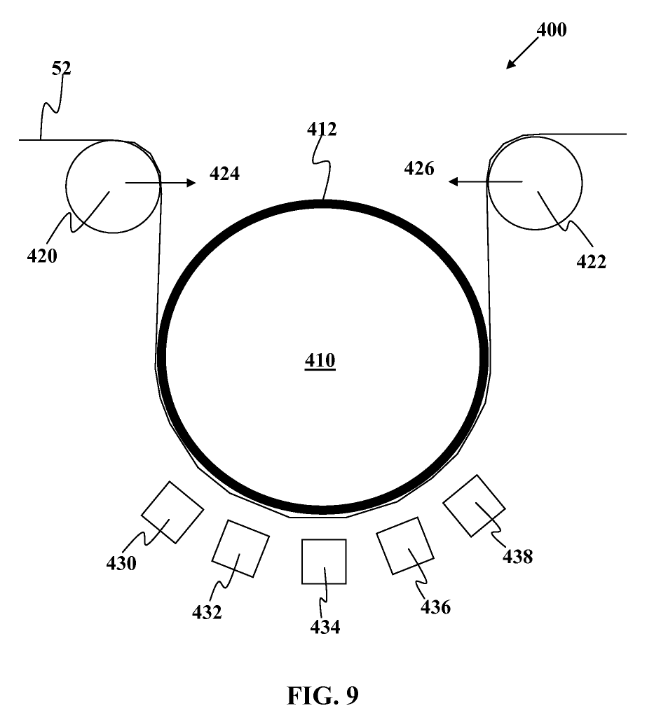

Referring now to FIG. 3, another embodiment of the present invention will now be described. FIG. 3 shows that at least three thermal masses 80 are used in the path downstream from a sputtering chamber. It should be understood that other numbers of masses may be used. Some embodiments may use less than three masses. In some embodiments, there are at least three thermal masses 80 after each of the sputtering chamber(s). By way of nonlimiting example, these thermal masses 80 may be rollers that roll with the substrate, stationary non-rolling devices that allow the substrate to slide over them, or combinations thereof. The system 100 of FIG. 3 shows that the additional rollers provide further areas of contact to provide thermal transfer that cools the substrate. Specifically, middle rollers 82 and 84 are included in the configuration to provide further surface contact with the substrate. The rollers 82 and 84 are also configured to contact the surface of the sputtered material to allow heat removal from that top surface in addition to heat removal from the bottom surface. It should be understood that one or more of the masses 80, or rollers 82 and 84 may be coated with a pliable but thermally conductive material to improve heat transfer between the substrate and those masses. If the substrate is not in full contact with the masses or rollers, there may be uneven and/or inefficient cooling of the substrate which may result in stresses that deform or otherwise corrupt the substrate. Some suitable materials are described in the text for FIG. 9. It should be understood that the pliable material may also be useful for those rollers which contact the top surface of the substrate which has the sputtered material.

FIGS. 2 and 3 also show the use of isolation sections 120 and 122 between the housings 124 and 126. These isolation sections may contain their own isolation rollers 130 and 132 which provide sufficient tension to the substrate 52 to allow the substrate to continue through all the chambers in a controlled manner, without substrate sagging or deformation due to uncontrolled or loosely control of the substrate through the system. In one embodiment, the path of the substrate may be sharply angled (greater than 90 degree turns/bends) to increase the normal force against the rollers. Optionally, the isolation sections 120 and 122 may also provide gas separation barrier between the housings 124 and 126. There may be a vacuum, a low vacuum, or sub-atmospheric environment in the isolation sections 120 and/or 122. Optionally, the isolation sections 120 and/or 122 may be filled a gas species such as nitrogen, noble gas, or other gas that is different from those in the sputter chambers. Optionally, the gas in the isolation sections 120 and/or 122 may be the same as that in one of the adjacent sputtering chamber(s).

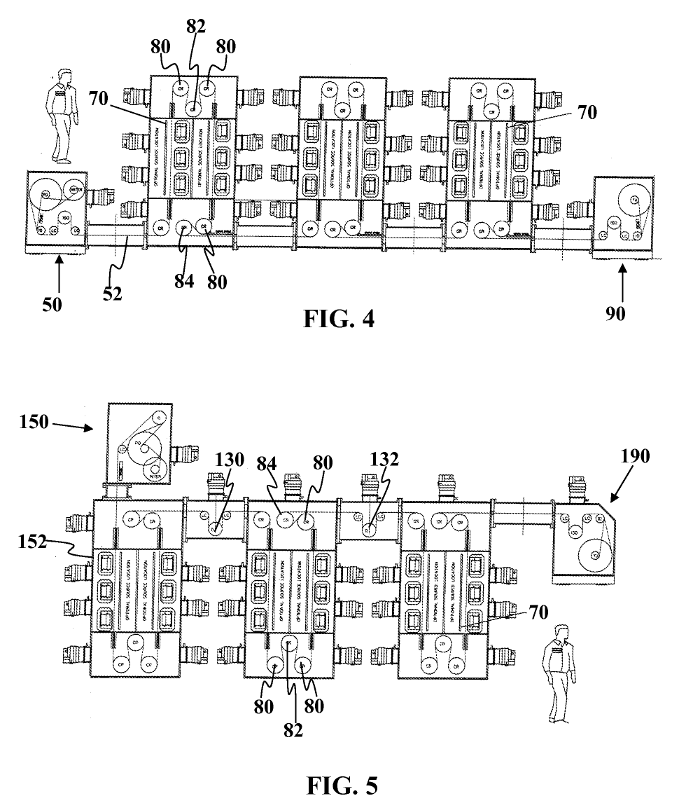

Referring now to FIG. 4, yet another embodiment of the present invention will now be described. This embodiment of the sputtering system is similar to that shown in FIG. 3. This present embodiment, however, have the intermediate isolation sections 120 and 122 of FIG. 3 removed. The elimination of the intermediate isolation section reduces the amount of equipment but also creates a longer web path without passing through tensioners. This sputtering system, along with the others disclosed herein, may also allow for sputtering on both surfaces of the substrate 52, depending on where the targets 60 are mounted in the sputtering chamber.

Referring now to FIG. 5, a still further embodiment of the present invention will now be described. This embodiment of the sputtering system shows that the unwind section 150 is positioned to more directly feed the substrate 52 into the first sputtering chamber without having to curve and guide the substrate through excessive numbers of rollers. This embodiment is particularly advantageous as no roller directly contacts the surface to be sputtered prior to the first sputtering in chamber 152. In the present embodiment, this direct feed may be accomplished by way of positioning the unwind section 150 above the first sputtering chamber 152. Optionally, this unwind or feed section 150 may be positioned below the chamber. So long as the feed path is aligned parallel to the path of the substrate in the sputtering chamber 152, there will be minimal contact with the to-be-sputtered surface. This allows the substrate material to be undisturbed during the unwinding process and allow the first sputtering to occur onto the undisturbed substrate. Isolation chambers may be positioned between the housing for the dual chambers to allow separation of gas species and/or to provide additional tension to the substrate 52.

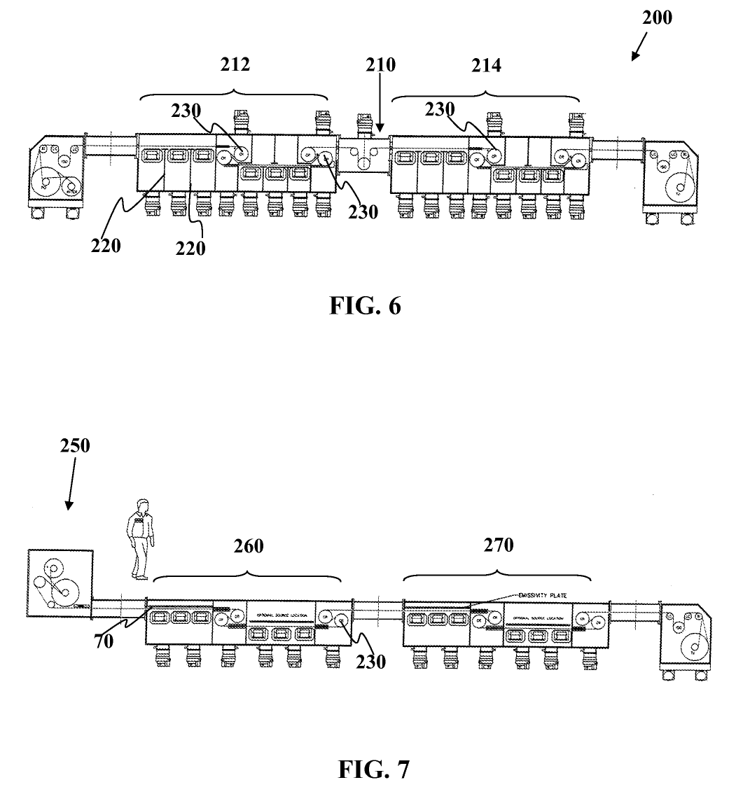

Referring now to FIG. 6, another embodiment of the present invention will now be described. FIG. 6 shows a linearly configured sputtering system 200 wherein the web path is substantially horizontal. This horizontal web path minimizes the height of the equipment and may facilitate servicing. There is only one isolation section 210 between the housings 212 and 214. In this embodiment, the surface that will be sputtered on is contacted by rollers prior to the deposition of the first sputtered layer. FIG. 6 also shows dividers 220 used to keep each magnetron under vacuum or sub-atmospheric pressure from its own vacuum pump. This embodiment also shows that some systems may be configured without an emissivity plate but use only thermally controller rollers 230 to regulate temperature.

Referring now to FIG. 7, another embodiment of the present invention will now be described. This embodiment shows a sputtering system similar that of FIG. 6. It includes a linearly configured sputtering system wherein the web path is minimized due to the fewer number of directional changes and the few number of sputtering chambers. This embodiment shows that the target surface of the substrate to be sputtered is not contacted by a roller of the unwind section 250 prior to deposition of the first layer of sputtered material. This is obtained in part by inverting the orientation of some components of the unwind section used in system 200. This embodiment also shows the use of emissivity unit 70, and optionally, along with the thermally controlled rollers. These elements may be contained in the housings 260 and 270. There is, however, no isolation section between the housings.

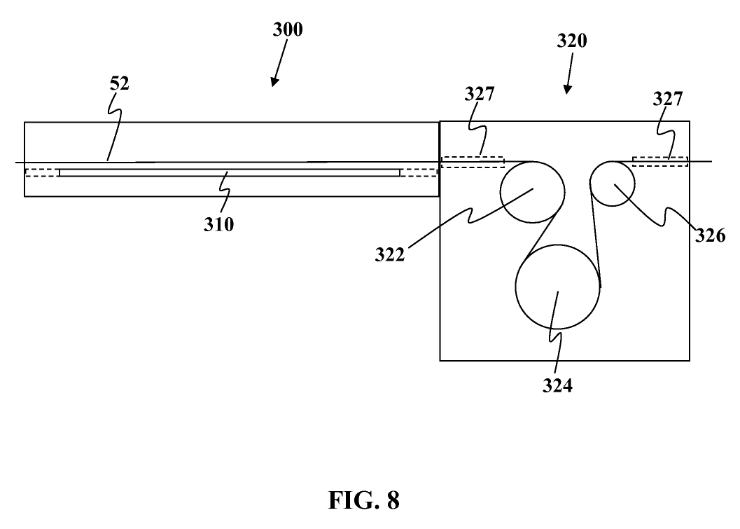

Referring now to FIG. 8, yet another embodiment of the present invention will now be described. This embodiment shows one portion of a sputtering or deposition system with a processing chamber 300 that contains an emissivity unit or mass 310. In the nonlimiting example where the system is used for sputtering, the sputtering chamber is coupled to a chilled roller section 320 wherein at least one roller 322 is mounted therein to bring the temperature of the substrate to a lower level. As seen in FIG. 8, more than one roller may be include in the chilled roller section 320 to bring the temperature to the desired range. Some embodiments may have additional temperature controlled rollers 324 and 326. The rollers 322, 324, and 326 may be of the same diameter, some with different diameters, or all of different diameters. By way of nonlimiting examples, the rollers may be “small” rollers with diameters less than the size of the supply roll. The positions of the rollers are such that they may be used to further tension the substrate 52 against the roller 324. These rollers and any of the rollers herein may optionally include a compliant, yet thermally conductive coating or layer such as that described in regards to FIG. 9. In some embodiments, all rollers in a system may have these coatings or other embodiments may only have some rollers that include this coating. It should also be understood that a plurality of the chambers 300 and/or 320 may be used in combination to provide multiple sputtering and/or cooling systems which may be used in various combination. By way of non-limiting example, there may be a sputter, cool, sputter, and cool system. This may be repeated in this sequence. Optionally, there may be two cooling sections between sputter sections. Optionally, some may use two sputter sections before using one or more cooling section. Pinch valves, load locks, or other separators 327 may optionally be included. It should be understood that some embodiments may have two or more deposition chambers before a cooling chamber is provided.

Referring now to FIG. 9, yet another embodiment of the present invention will now be described. This embodiment shows a sputtering system 400 wherein a rotary sputtering apparatus is used. Specifically, the system has a rotary drum 410 that is thermally controlled to maintain the temperature of the substrate 52 within a desired range. Proper temperature control minimizes damage to the substrate which may warp, deform, or be otherwise damaged as temperatures exceed the operating range. The rotary drum 410 may include a compliant layer 412 that allows for improved surface contact between the underside of the substrate 52 and the layer 412. This improved contact improves the heat transfer between the substrate 52 and the drum 410. The compliant layer 412 may comprise of a thermally conductive yet pliable material. In some embodiments, the material may comprise of a polymer material with thermally conductive beads. Layer 412 may contain particles dispersed in the layers to improve thermal conductivity. These particles may be of various shapes and/or sizes. The particle shapes may be spherical, rod-like, polygonal, or combinations thereof. Particles may also be made from only one material. Optionally, some particles may be of one material while others are of one or more other materials. The particles are preferably of a material that is electrically insulating and highly thermally conductive. Optionally, the particles may be formed from an electrically conductive and thermally conductive material. If the material is both thermally and electrically conductive, the particles are preferably held in a material that is electrically insulating. In this manner, the electrical insulating properties are maintained while the thermal conductivity properties are improved. By way of nonlimiting example, the particles may be made of one or more of the following materials: alumina, aluminum nitride, boron nitride, zinc oxide, beryllia, silicon, diamond, isotopically pure synthetic single crystal diamond, and/or combinations thereof. A commercially available form of aluminum nitride sold under the trade name Hi-Therm™ Aluminum Nitride is also suitable for use with the present invention. Other embodiments of the present invention may use micronized silver with dispersing agents on the particles to disperse them in the material. Some of the particles may be coated with alumina (such as by anodization or ALD) to facilitate dispersion in the layer. In one embodiment, the particles may be as large as the thickness of the compliant layer. In other embodiments, the particles are smaller than the thickness of the compliant layer. In still other embodiments, the particles are significantly smaller than the thickness of the compliant layer.

In one embodiment, the layer may be comprised of one or more of the following materials (mixed with the particles): ethyl vinyl acetate (EVA), polyvinyl butyral (PVB), ionomer, silicone, thermoplastic polyurethane (TPU), thermoplastic elastomer polyolefin (TPO), tetrafluoroethylene hexafluoropropylene vinylidene (THV), fluorinated ethylene-propylene (FEP), saturated rubber, butyl rubber, thermoplastic elastomer (TPE), flexibilized epoxy, epoxy, amorphous polyethylene terephthalate (PET), urethane acrylic, acrylic, other fluoroelastomers, or combinations thereof. Optionally, the layer may be comprised of one or more of the following (mixed with the particles): PET, polyethylene naphthalate (PEN), polyvinylfluoride (PVF), ethylene tetrafluoroethylene (ETFE), Poly(vinylidene fluoride) (PVDF), polychlorotrifluoroethylene (PCTFE), FEP, THV, fluoroelasomer, fluoropolymer, polyamide, polyimide, polyester, or combinations thereof.

The substrate 52 may be tensioned against the drum 410 by use of tensioners 420 and 422. The tensioners 420 and 422 may be moved closer as indicated by arrows 424 and 426 to increase the normal force of the substrate 52 against the drum 410. A plurality of magnetron sputtering targets 430, 432, 434, 436, and 438 are positioned to sputter material on to the substrate 52 while the substrate 52 is in contact with the drum 410. The number of targets and types of materials may vary as desired.

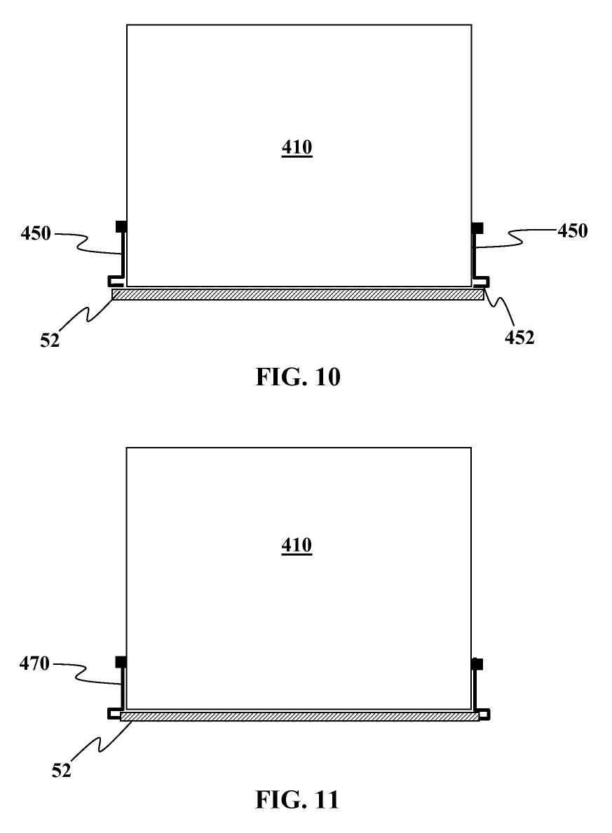

Referring now to FIG. 10, another embodiment of the present invention will now be described. FIG. 10 shows a cross-sectional view of a system similar to the system 400. This embodiment shows that sputter shields 450 are positioned along the sides of the drum 410. The shields 450 protect the sidewalls of the drum 410 and may be considered consumable parts. The shields 450 may have a surface 452 that rides against and supports the underside of the substrate 52. Although not limited to the following, this embodiment has the substrate 52 at a width wider than that of the drum 410. It should also be understood that the shield may be of other shapes. The shield may be comprised of various materials used for sputter shields or materials used for the chambers. In one embodiment, the shield 450 may be comprised of stainless steel, aluminum, copper, titanium, molybendum, alloys of the aforementioned, polymers, metallized polymers, aluminum oxide, mullite, fused silica, and/or glasses.

FIG. 11 shows another embodiment of the sputter shield 470. This embodiment shows the shield may protect the underside and that it may also protect the side of the substrate 52. The shield may be comprised of various materials used for sputter shields or materials used for the chambers. In one embodiment, the shield 470 may be comprised of stainless steel, aluminum, copper, titanium, molybendum, alloys of the aforementioned, polymers, metallized polymers, aluminum oxide, mullite, fused silica, and/or glasses.

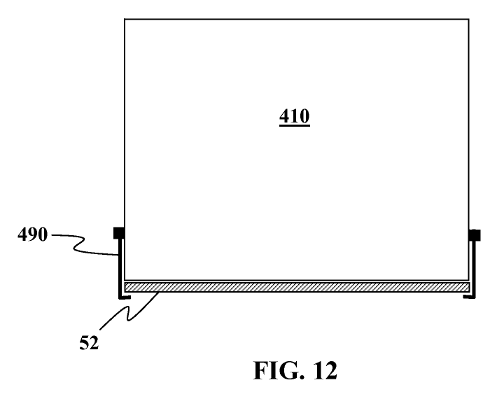

FIG. 12 shows another embodiment of the sputter shield 490. This embodiment of the sputter shield 490 is designed to protect the underside of the substrate 52 and the shield 490 also extends above a portion of the substrate 52. This allows the substrate 52 to be at the same width or shorter width that the width of the drum 410. The shield may be comprised of various materials used for sputter shields or materials used for the chambers. In one embodiment, the shield 490 may be comprised of stainless steel, aluminum, copper, titanium, molybendum, alloys of the aforementioned, polymers, metallized polymers, aluminum oxide, mullite, fused silica, and/or glasses. It should also be understood that other shaped shields may also be used so long as the prevent sputter material from reaching the sides or others surfaces of the drum. The sputter shield 490 may be formed as plurality of individual pieces that may or may not overlap. In one embodiment, the sputter shield 490 may be formed in a “pie” like configuration for protecting a rotary drum (i.e. entire shield is circular but individual pieces are wedge shaped). Other shields may be shaped to follow the path of the substrate and protect those non-substrate parts which may be exposed to sputtering.

While the invention has been described and illustrated with reference to certain particular embodiments thereof, those skilled in the art will appreciate that various adaptations, changes, modifications, substitutions, deletions, or additions of procedures and protocols may be made without departing from the spirit and scope of the invention. For example, with any of the above embodiments, although sputtering is described, other deposition processes may also benefit from the use of the above techniques. The tool designs of this invention may also be used for continuous, in-line processing of substrates which may be in the form of a web or in the form of large sheets such as glass sheets which may be fed into the reactor in a continuous manner. Depending on the material being sputtered in the chamber, the gas may be an inert gas such as nitrogen, argon or helium or a reducing gas such as a mixture of hydrogen (e.g. 2-5% mixture) with any inert gas. The material to be sputtered in the chamber may be a group IB, IIIA, and/or VIA material. The system may be used to sputter Cu—In, In—Ga, Cu—Ga, Cu—In—Ga, Cu—In—Ga—S, Cu—In—Ga—Se, other absorber materials, IB-IIB-IVA-VIA absorbers, or other alloys. The system may be used to sputter transparent oxide material such as AZO, ITO, i-AZO, or other transparent electrode material. It may also be used to sputter molybdenum, chromium, vanadium, tungsten, and glass, or compounds such as nitrides (including but not limited to titanium nitride, tantalum nitride, tungsten nitride, vanadium nitride, silicon nitride, or molybdenum nitride), oxynitrides (including but not limited to oxynitrides of Ti, Ta, V, W, Si, or Mo), oxides, and/or carbides. Again, any of these may be deposited on the substrate or on the coated substrate. Some substrates may have different materials on one side than the other. The thickness of the various layers may be varied based on the time spent inside one chamber or time spent in multiple chambers. The same path may use chambers that sputter the same material, deposit two or more different materials (simultaneously, in a reactive process, or sequentially). There may be a series of hot-followed-by-cold processes where sawtooth action where temperature rises during deposition, is cooled, then rises again during the next deposition process (which may be the same or different), and wherein at no point does the temperature exceed a maximum pre-set temperature.

Furthermore, those of skill in the art will recognize that any of the embodiments of the present invention can be applied to almost any type of solar cell material and/or architecture. For example, the absorber layer in solar cell 10 may be an absorber layer comprised of silicon, amorphous silicon, organic oligomers or polymers (for organic solar cells), bi-layers or interpenetrating layers or inorganic and organic materials (for hybrid organic/inorganic solar cells), dye-sensitized titania nanoparticles in a liquid or gel-based electrolyte (for Graetzel cells in which an optically transparent film comprised of titanium dioxide particles a few nanometers in size is coated with a monolayer of charge transfer dye to sensitize the film for light harvesting), copper-indium-gallium-selenium (for CIGS solar cells), CdSe, CdTe, Cu(In,Ga)(S,Se)₂, Cu(In,Ga,Al)(S,Se,Te)₂, and/or combinations of the above, where the active materials are present in any of several forms including but not limited to bulk materials, micro-particles, nano-particles, or quantum dots. The CIGS cells may be formed by vacuum or non-vacuum processes. The processes may be one stage, two stage, or multi-stage CIGS processing techniques. Additionally, other possible absorber layers may be based on amorphous silicon (doped or undoped), a nanostructured layer having an inorganic porous semiconductor template with pores filled by an organic semiconductor material (see e.g., US Patent Application Publication US 2005-0121068 A1, which is incorporated herein by reference), a polymer/blend cell architecture, organic dyes, and/or C₆₀ molecules, and/or other small molecules, micro-crystalline silicon cell architecture, randomly placed nanorods and/or tetrapods of inorganic materials dispersed in an organic matrix, quantum dot-based cells, or combinations of the above. Many of these types of cells can be fabricated on flexible substrates.

Additionally, concentrations, amounts, and other numerical data may be presented herein in a range format. It is to be understood that such range format is used merely for convenience and brevity and should be interpreted flexibly to include not only the numerical values explicitly recited as the limits of the range, but also to include all the individual numerical values or sub-ranges encompassed within that range as if each numerical value and sub-range is explicitly recited. For example, a thickness range of about 1 nm to about 200 nm should be interpreted to include not only the explicitly recited limits of about 1 nm and about 200 nm, but also to include individual sizes such as but not limited to 2 nm, 3 nm, 4 nm, and sub-ranges such as 10 nm to 50 nm, 20 nm to 100 nm, etc. . . .

The publications discussed or cited herein are provided solely for their disclosure prior to the filing date of the present application. Nothing herein is to be construed as an admission that the present invention is not entitled to antedate such publication by virtue of prior invention. Further, the dates of publication provided may be different from the actual publication dates which may need to be independently confirmed. All publications mentioned herein are incorporated herein by reference to disclose and describe the structures and/or methods in connection with which the publications are cited.

While the above is a complete description of the preferred embodiment of the present invention, it is possible to use various alternatives, modifications and equivalents. Therefore, the scope of the present invention should be determined not with reference to the above description but should, instead, be determined with reference to the appended claims, along with their full scope of equivalents. Any feature, whether preferred or not, may be combined with any other feature, whether preferred or not. In the claims that follow, the indefinite article “A”, or “An” refers to a quantity of one or more of the item following the article, except where expressly stated otherwise. The appended claims are not to be interpreted as including means-plus-function limitations, unless such a limitation is explicitly recited in a given claim using the phrase “means for.”

What is claimed is:

1. A sputtering system for use with a substrate, the system comprising:
a sputtering chamber;
at least one magnetron disposed in the chamber;
at least one emissivity unit located within the chamber for drawing heat away from the substrate.

2. A sputtering system for use with a substrate, the system comprising:
a sputtering chamber;
at least one magnetron disposed in the chamber;
at least one cooling device positioned along the path of the substrate to come into physical contact with the substrate; and
at least one emissivity-based heat sink located within the chamber for drawing heat away from the substrate.

3. The system of claim 1 wherein the cooling device is located outside the sputtering chamber.

4. The system of claim 1 wherein the cooling device is located inside the sputtering chamber.

5. The system of claim 1 wherein the cooling device comprises of a chilled roller.

6. The system of claim 1 wherein the cooling device comprises of a chilled roller with a pliable coating on the roller.

7. The system of claim 1 wherein the cooling device comprises of a chilled roller.

8. The system of claim 1 wherein the cooling device cools by way of conduction.

9. The system of claim 1 further comprising a tensioner positioned to pull the substrate against the cooling device for improved surface contact.

10. The system of claim 1 further comprising a tensioner positioned to push the substrate against the cooling device for improved surface contact.

11. The system of claim 1 further comprising a plurality of cooling devices positioned along the path of the substrate.

12. The system of claim 11 wherein the cooling devices are positioned along the path of the substrate in an arrangement that increases normal force of the substrate against at least one surface of at least one of the cooling devices.

13. The system of claim 11 wherein the cooling devices are positioned along the path of the substrate in an arrangement wherein the devices only contact a backside surface of the substrate.

14. The system of claim 11 wherein the cooling devices are positioned along the path of the substrate in an arrangement wherein at least one of the devices contacts a backside surface of the substrate and at least one of the devices contacts a frontside surface of the substrate at the same or different location along the path.

15. The system of claim 1 further comprising at least a second sputtering chamber arranged to receive the substrate.

16. The system of claim 15 wherein the second sputtering chamber includes at least one cooling device positioned along the path of the substrate to come into physical contact with the substrate; and at least one emissivity-based heat sink located within the chamber for drawing heat away from the substrate.

17. The system of claim 15 further comprising at least one cooling section between the sputtering chamber and the second sputtering chamber.

18. A sputtering system for use with a substrate, the system comprising:
a sputtering chamber;
at least one magnetron disposed in the chamber;
at least one conduction-based cooling system positioned along the path of the substrate; and
a cooling system to reduce the temperature of the substrate while the substrate is in the chamber, wherein the cooling system is not a chamber wall and is in an arrangement to cool the substrate by way of emissivity cooling.

19. The system of claim 18 wherein the cooling system comprises of at least one emissivity mass positioned at least partially inside the chamber.

20. The system of claim 18 wherein the cooling system comprises of at least one emissivity plate positioned at least partially inside the chamber.
